(19) United States
(12) Patent Application Publication
(10) Pub. No.: US 2007/0080697 A1
(43) Pub. Date: Apr. 12, 2007

(54) Semiconductor device tester pin contact resistance measurement

(75) Inventors: Chih-Chiang Tseng, Fremont, CA (US); Patrick T. Chuang, Cupertino, CA (US); Chungji Lu, Sunnyvale, CA (US)

Correspondence Address: Jonathan O. Owens;HAVERSTOCK & OWENS LLP, 162 North Wolfe Road, Sunnyvale, CA, 94086, US

(73) Assignees: Sony Corporation; Sony Electronics Inc.

(21) Appl. No.: 11/413,219

(22) Filed: Apr. 28, 2006

Related U.S. Application Data
(60) Provisional application No. 60/721,006, filed on Sep. 27, 2005.

(51) Int. Cl. G01R 27/08

(52) U.S. Cl. 324/691

(57) ABSTRACT

A contact resistance measuring circuit is configured to determine the contact resistance of a testing device. The measuring circuit is coupled to a processing circuit and the testing device. The measuring circuit includes a pair of input/output units coupled together via a pass device. Each of the input/output units includes a pull-up device and a pull-down device to provide separate pull-up and pull-down control, respectively. The pull-up devices, the pull-down devices, and the pass device are dynamically configurable such that the measuring circuit uses either a pull-up mode or a pull-down mode to measure voltage and current characteristics of each contact point, or pin, of the testing device. The processing circuit calculates the contact resistance for each pin according to the measured voltage and current characteristics. The calculated contact resistances are used to calibrate the testing device.

### RELATED APPLICATIONS

This application claims priority under 35 U.S.C. 119(e) of the co-pending U.S. Provisional Patent Application No. 60/721,006, filed Sep. 27, 2005, and entitled “SEMICONDUCTOR DEVICE TESTER PIN CONTACT RESISTANCE MEASUREMENT.” U.S. Provisional Patent Application No. 60/721,006, filed Sep. 27, 2005, and entitled “SEMICONDUCTOR DEVICE TESTER PIN CONTACT RESISTANCE MEASUREMENT” in also hereby incorporated by reference.

### FIELD OF THE INVENTION

The present invention relates to the field of semiconductor testing devices. More particularly, the present invention relates to the field of measuring the pin contact resistance of semiconductor testing devices.

### BACKGROUND OF THE INVENTION

For high speed applications, such as those performed using high speed integrated circuits (ICs), the output impedance of the high speed device needs to be precisely controlled. Testing devices include tester contact pins through which a device under test is connected to the testing device. Each tester contact pin includes some amount of resistance. In order to properly test the input/output impedance of the device under test, the contact resistance of each tester contact pin needs to be known.

High speed ICs need to accurately control I/O impedance to achieve a high speed data transfer rate. The accuracy of an I/O impedance measurement is very challenging due to the contact resistance of the tester contact pins. A typical contact resistance of a tester contact pin is 1-5 ohms. For a high speed IC with an I/O impedance of 50 ohms, a 5 ohm contact resistance is 10%. The performance specifications for a typical high speed application require the I/O impedance to be within 10% of the target value. Therefore, it is difficult to test the device impedance without knowing the contact resistance of the tester contact pins.

### SUMMARY OF THE INVENTION

A contact resistance measuring circuit is configured to determine the contact resistance of a testing device. The measuring circuit is coupled to a processing circuit and the testing device. The measuring circuit includes a pair of input/output units coupled together via a pass device. Each of the input/output units includes a pull-up device and a pull-down device to provide separate pull-up and pull-down control, respectively. The pull-up devices, the pull-down devices, and the pass device are dynamically configurable such that the measuring circuit uses either a pull-up mode or a pull-down mode to measure voltage and current characteristics of each contact point, or pin, of the testing device. The processing circuit calculates the contact resistance for each pin according to the measured voltage and current characteristics. The calculated contact resistances are used to calibrate the testing device. The contact resistances are calculated each time a device under test is connected to the testing device.

In one aspect, a method of determining a contact resistance of a testing device is described. The method includes coupling a first pin of the testing device to a first pull-up device and coupling a second pin of the testing device to a second pull-up device, coupling the first pull-up device to the second pull-up device via a pass device, configuring the first pull-up device and the pass device to an on-state, configuring the second pull-up device to an off-state, thereby configuring the second pull-up device as a high impedance circuit path, applying a first voltage to the first, measuring a first current entering the first pin, measuring a second voltage at the second pin, and calculating a contact resistance of the first pin according to the applied first voltage, the measured second voltage, and the measured first current. The method can also include coupling a first pull-down device in series with the first pull-up device such that the first pin is coupled to a first terminal of the first pull-up device and to a first terminal of the first pull-down device. The method can also include configuring the first pull-down device to an off-state. The method can also include coupling a second pull-down device in series with the second pull-up device such that the second pin is coupled to a first terminal of the second pull-up device and to a first terminal of the second pull-down device. The method can also include configuring the second pull-down device to an off-state. The method can also include coupling a second terminal of the first pull-up device and a second terminal of the second pull-up device to a power source and coupling a second terminal of the first pull-down device and a second terminal of the second pull-down device to ground. The contact resistance of the first pin can be represented as a first resistor and the contact resistance of the second pin is represented as a second resistor. Coupling the first pin to the first pull-up device can comprise coupling a first terminal of the first resistor to the first pull-up device, applying the first voltage to the first pin comprises applying the first voltage to a second terminal of the first resistor, and measuring the first current entering the first pin comprises measuring the first current at the first terminal of the first resistor. Coupling the second pin to the second pull-up device can comprise coupling a first terminal of the second resistor to the second pull-up device, and measuring the second voltage at the second pin comprises measuring the second voltage at a second terminal of the second resistor. The method can also include configuring the second pull-up device and the pass device to an on-state, configuring the first pull-up device to an off-state, thereby configuring the first pull-up device as a high impedance circuit path, removing the applied first voltage from the first pin, applying a third voltage to the second pin, measuring a second current entering the second pin, measuring a fourth voltage at the second pin, and calculating a contact resistance of the second pin according to the applied third voltage, the measured fourth voltage, and the measured second current. Configuring a device to the on-state can comprise applying a logical high signal to the device, and configuring the device to the off-state comprises applying a logical low signal to the device.

In another aspect, a method of determining a contact resistance of a testing device is described. The method includes coupling a first pin of the testing device to a first pull-down device and coupling a second pin of the testing device to a second pull-down device, coupling the first pull-down device to the second pull-down device via a pass device, configuring the first pull-down device and the pass device to an on-state, configuring the second pull-down device to an off-state, thereby configuring the second pull-down device as a high impedance circuit path, applying a first voltage to the first pin, measuring a first current being output from the first pin, measuring a second voltage at the second pin, and calculating a contact resistance of the first pin according to the applied first voltage, the measured second voltage, and the measured first current. The method can also include coupling a first pull-up device in series with the first pull-down device such that the first pin is coupled to a first terminal of the first pull-up device and to a first terminal of the first pull-down device. The method can also include configuring the first pull-up device to an off-state. The method can also include coupling a second pull-up device in series with the second pull-down device such that the second pin is coupled to a first terminal of the second pull-up device and to a first terminal of the second pull-down device. The method can also include configuring the second pull-up device to an off-state. The method can also include coupling a second terminal of the first pull-up device and a second terminal of the second pull-up device to a power source and coupling a second terminal of the first pull-down device and a second terminal of the second pull-down device to ground. The contact resistance of the first pin can be represented as a first resistor and the contact resistance of the second pin is represented as a second resistor. Coupling the first pin to the first pull-down device can comprise coupling a first terminal of the first resistor to the first pull-down device, applying the first voltage to the first pin comprises applying the first voltage to a second terminal of the first resistor, and measuring the first current being output from the first pin comprises measuring the first current at the first terminal of the first resistor. Coupling the second pin to the second pull-down device can comprise coupling a first terminal of the second resistor to the second pull-down device, and measuring the second voltage at the second pin comprises measuring the second voltage at a second terminal of the second resistor. The method can also include configuring the second pull-down device and the pass device to an on-state, configuring the first pull-down device to an off-state, thereby configuring the first pull-down device as a high impedance circuit path, removing the applied first voltage from the first pin, applying a third voltage to the second pin, measuring a second current being output from the second pin, measuring a fourth voltage at the second pin, and calculating a contact resistance of the second pin according to the applied third voltage, the measured fourth voltage, and the measured second current. Configuring a device to the on-state can comprise applying a logical high signal to the device, and configuring the device to the off-state comprises applying a logical low signal to the device.

In yet another aspect, a circuit to determine a contact resistance of a testing device is described. The circuit includes a first pull-up device coupled to a first pin of the testing device, wherein the first pull-up device is configured to be dynamically set to either an on-state or an off-state, a second pull-up device coupled to a second pin of the testing device, wherein the second pull-up device is configured to be dynamically set to either an on-state or an off-state, and a pass device including a first terminal and a second terminal, wherein the first terminal is coupled to the first pin and to the first pull-up device, and the second terminal is coupled to the second pin and to the second pull-up device, further wherein the pass device is configured to be dynamically set to either an on-state or an off-state, wherein the circuit is configured such that when the first pull-up device is set to the on-state, the pass device is set to the on-state, the second pull-up device is set to the off-state and a first voltage is applied to the first pin, a first current entering the first pin is measured and a second voltage at the second pin is measured to calculate a contact resistance of the first pin. The circuit can also include a processing circuit configured to calculate the contact resistance of the first pin according to the applied first voltage, the measured second voltage, and the measured first current. The circuit can also include a first pull-down device coupled in series with the first pull-up device such that the first pin is coupled to a first terminal of the first pull-up device and to a first terminal of the first pull-down device. The first pull-down device can be set to an off-state. The circuit can also include a second pull-down device coupled in series with the second pull-up device such that the second pin is coupled to a first terminal of the second pull-up device and to a first terminal of the second pull-down device. The second pull-down device can be set to an off-state. A second terminal of the first pull-up device and a second terminal of the second pull-up device can be coupled to a power source and a second terminal of the first pull-down device and a second terminal of the second pull-down device can be coupled to ground. The contact resistance of the first pin can be represented as a first resistor and the contact resistance of the second pin is represented as a second resistor. A first terminal of the first resistor can be coupled to the first pull-up device, the first voltage can be applied to a second terminal of the first resistor, and the first current can be measured at the first terminal of the first resistor. A first terminal of the second resistor can be coupled to the second pull-up device, and the second voltage can be measured at a second terminal of the second resistor. The circuit can be configured such that when the second pull-up device and the pass device are set to the on-state, the first pull-up device is set to the off-state, the applied first voltage is removed from the first pin, and a third voltage is applied to the second pin, a second current entering the second pin is measured and a fourth voltage is measured at the second pin to calculate a contact resistance of the second pin. The circuit can also include a processing circuit configured to calculate the contact resistance of the second pin according to the applied third voltage, the measured fourth voltage, and the measured second current. A device can be configured to the on-state by applying a logical high signal to the device, and the device is configured to the off-state by applying a logical low signal to the device. The testing device can comprise a semiconductor testing device.

In still yet another aspect, a circuit to determine a contact resistance of a testing device is described. The circuit includes a first pull-down device coupled to a first pin of the testing device, wherein the first pull-down device is configured to be dynamically set to either an on-state or an off-state, a second pull-down device coupled to a second pin of the testing device, wherein the second pull-down device is configured to be dynamically set to either an on-state or an off-state, and a pass device including a first terminal and a second terminal, wherein the first terminal is coupled to the first pin and to the first pull-down device, and the second terminal is coupled to the second pin and to the second pull-down device, further wherein the pass device is configured to be dynamically set to either an on-state or an off-state, wherein the circuit is configured such that when the first pull-down device is set to the on-state, the pass device is set to the on-state, the second pull-down device is set to the off-state and a first voltage is applied to the first pin, a first current being output by the first pin is measured and a second voltage at the second pin is measured to calculate a contact resistance of the first pin. The circuit can also include a processing circuit configured to calculate the contact resistance of the first pin according to the applied first voltage, the measured second voltage, and the measured first current. The circuit can also include a first pull-up device coupled in series with the first pull-down device such that the first pin is coupled to a first terminal of the first pull-up device and to a first terminal of the first pull-down device. The first pull-up device can be set to an off-state. The circuit can also include a second pull-up device coupled in series with the second pull-down device such that the second pin is coupled to a first terminal of the second pull-up device and to a first terminal of the second pull-down device. The second pull-up device can be set to an off-state. A second terminal of the first pull-up device and a second terminal of the second pull-up device can be coupled to a power source and a second terminal of the first pull-down device and a second terminal of the second pull-down device can be coupled to ground. The contact resistance of the first pin can be represented as a first resistor and the contact resistance of the second pin can be represented as a second resistor. A first terminal of the first resistor can be coupled to the first pull-down device, the first voltage can be applied to a second terminal of the first resistor, and the first current can be measured at the first terminal of the first resistor. A first terminal of the second resistor can be coupled to the second pull-down device, and the second voltage can be measured at a second terminal of the second resistor. The circuit can be configured such that when the second pull-down device and the pass device are set to the on-state, the first pull-down device is set to the off-state, the applied first voltage is removed from the first pin, and a third voltage is applied to the second pin, a second current entering the second pin is measured and a fourth voltage is measured at the second pin to calculate a contact resistance of the second pin. The circuit can also include a processing circuit configured to calculate the contact resistance of the second pin according to the applied third voltage, the measured fourth voltage, and the measured second current. A device can be configured to the on-state by applying a logical high signal to the device, and the device can be configured to the off-state by applying a logical low signal to the device. The testing device can comprise a semiconductor testing device.

In another aspect, a system to determine a contact resistance of a testing device is described. The system includes the testing device including a first pin and a second pin, a measuring circuit coupled to the measuring device and configured to measure a voltage drop across the first pin of the testing device when a first voltage is applied to the first pin, to measure a first current flowing through the first pin when the first voltage is applied to the first pin, and to measure a second voltage at the second pin of the testing device when the first voltage is applied to the first pin, and a processing circuit coupled to the measuring circuit and configured to calculate a contact resistance of the first pin according to the applied first voltage, the measured second voltage, and the measured first current. The measuring circuit can also include one or more pull-up devices and a pass device dynamically configurable to enable the first current to flow through the first pin and to prevent a second current from flowing through the second pin. The measuring circuit can also include one or more pull-down devices and a pass device dynamically configurable to enable the first current to flow through the first pin and to prevent a second current from flowing through the second pin. The measuring circuit can be configured such that when the first voltage is removed from the first pin and a third voltage is applied to the second pin, the circuit measures a voltage drop across the second pin of the testing device, the circuit measures a second current flowing through the second pin, and the circuit measures a fourth voltage at the first pin of the testing device. The processing circuit can be configured to calculate a contact resistance of the second pin according to the applied third voltage, the measured fourth voltage, and the measured second current.

### BRIEF DESCRIPTION OF THE DRAWINGS

FIG. 1 illustrates an exemplary block diagram of a system for measuring the contact resistance of a semiconductor testing device.

FIG. 2 illustrates a conceptual diagram of the measuring circuit in FIG. 1.

FIG. 3 illustrates an exemplary implementation of the conceptual measuring circuit in FIG. 2.

FIG. 4 illustrates a conceptual diagram of the measuring circuit configured to measure the contact resistance of the pin A using the pull-up mode.

FIG. 5 illustrates an implementation of the conceptual measuring circuit in FIG. 4.

FIG. 6 illustrates a conceptual diagram of the measuring circuit configured to measure the contact resistance of the pin B using the pull-up mode.

FIG. 7 illustrates an implementation of the conceptual measuring circuit in FIG. 6.

FIG. 8 illustrates a conceptual diagram of the measuring circuit configured to measure the contact resistance of the pin A using the pull-down mode.

FIG. 9 illustrates an implementation of the conceptual measuring circuit in FIG. 8.

FIG. 10 illustrates a conceptual diagram of the measuring circuit configured to measure the contact resistance of the pin B using the pull-down mode.

FIG. 11 illustrates an implementation of the conceptual measuring circuit in FIG. 10.

Embodiments of the contact resistance measuring circuit are described relative to the several views of the drawings. Where appropriate and only where identical elements are disclosed and shown in more than one drawing, the same reference numeral will be used to represent such identical elements.

### DETAILED DESCRIPTION OF THE EMBODIMENTS

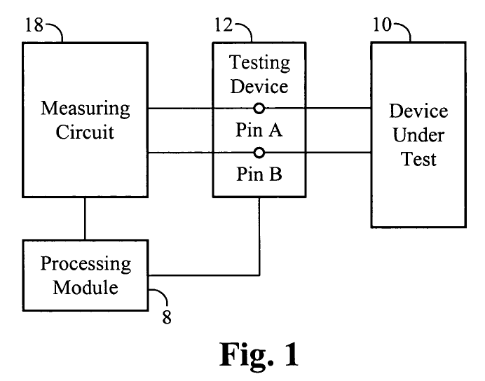

FIG. 1 illustrates an exemplary block diagram of a system for measuring the contact resistance of a semiconductor testing device 12. The testing device is any conventional testing device used to perform one or more tests related to the performance of a device under test 10. The testing device 12 provides connectivity to the device under test 10 at the pin A and the pin B. A contact resistance exists at the pin A and at the pin B. A measuring circuit 18 is coupled to the testing device 12 at the pin A and at the pin B. The measuring circuit 18 is configured to measure current and voltage characteristics used to determine the contact resistance associated with the pin A and the contact resistance associated with the pin B. A processing module 8 is coupled to the measuring circuit 18 and to the testing device 12. The processing module 8 provides control signals to the measuring circuit 18. The processing module 8 also calculates the contact resistance of the pin A and the contact resistance of the pin B according to the current and voltage characteristics measured by the measuring circuit 18. The processing module 8 provides the calculated contact resistances to the testing device 12 for proper calibration.

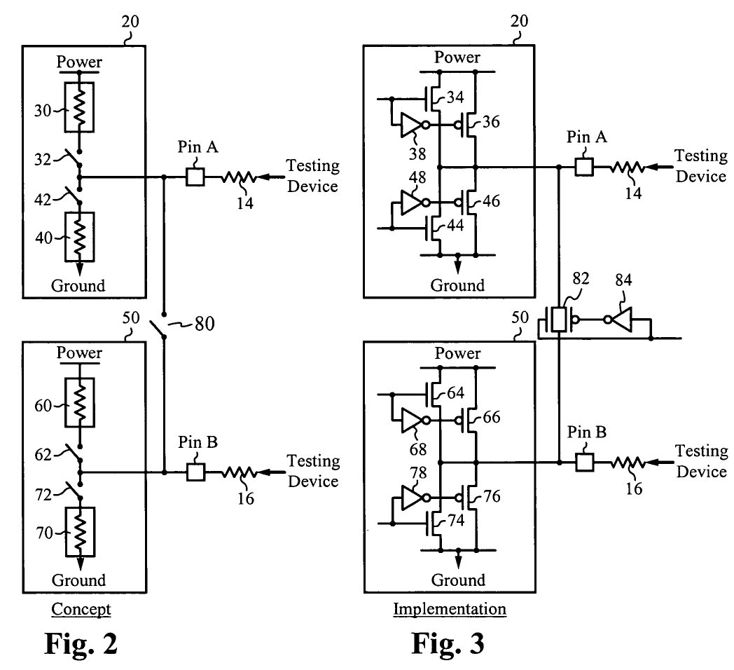

FIG. 2 illustrates a conceptual diagram of the measuring circuit 18 in FIG. 1. The measuring circuit 18 is coupled to the pin A and the pin B of the testing device 12. The contact resistance of the pin A is represented as a resistor 14. The contact resistance of the pin B is represented as a resistor 16. The measuring circuit 18 includes two input/output (I/O) units, an I/O unit 20 and an I/O unit 50. The I/O unit 20 is coupled to the I/O unit 50 via a switch 80. A first terminal of the resistor 14 is coupled to a first terminal of the switch 80 and the I/O unit 20. A first terminal of the resistor 16 is coupled to a second terminal of the switch 80 and the I/O unit 50.

The I/O unit 20 includes a pull-up device 30, a switch 32, a switch 42, and a pull-down device 40. The pull-up device 30 is coupled to a power source and to a first terminal of the switch 32. A second terminal of the switch 32 is coupled to a first terminal of the switch 42. The pull-down device 40 is coupled to a second terminal of the switch 42 and to ground. The second terminal of the switch 32 and the first terminal of the switch 42 are coupled to the first terminal of the resistor 14 and to the first terminal of the switch 80.

The I/O unit 50 includes a pull-up device 60, a switch 62, a switch 72, and a pull-down device 70. The pull-up device 60 is coupled to the power source and to a first terminal of the switch 62. A second terminal of the switch 62 is coupled to a first terminal of the switch 72. The pull-down device 70 is coupled to a second terminal of the switch 72 and to ground. The second terminal of the switch 62 and the first terminal of the switch 72 are coupled to the first terminal of the resistor 16 and to the second terminal of the switch 80.

FIG. 3 illustrates an exemplary implementation of the conceptual measuring circuit 18 in FIG. 2. The switch 80 in FIG. 2 is implemented as a transistor pair 82 coupled to an inverter 84. The pull-up device 30 of FIG. 2 is implemented as a PMOS transistor 34, an NMOS transistor 36 and an inverter 38. The transistor 34 and the transistor 36 are configured in parallel. The source of the transistor 34 and the drain of the transistor 36 are coupled to the power source. An input terminal of the inverter 38 is coupled to the gate of the transistor 34, and an output terminal of the inverter 38 is coupled to the gate of the transistor 36. The switch 32 in FIG. 2 is implemented by applying a logic signal to the gate of the transistor 34 and to the input terminal of the inverter 38. Applying a logic value 0 conceptually “opens” the switch 32. Applying a logic value 1 conceptually “closes” the switch 32. Controlling the switch 32 provides pull-up control of the I/O unit 20.

The pull-down device 40 in FIG. 2 is implemented as a PMOS transistor 44, an NMOS transistor 46, and an inverter 48. The transistor 44 and the transistor 46 are configured in parallel. The drain of the transistor 44 and the source of the transistor 46 are coupled to ground. An input terminal of the inverter 48 is coupled to the gate of the transistor 44. An output terminal of the inverter 48 is coupled to the gate of the transistor 46. The switch 42 in FIG. 2 is implemented by applying a logic signal to the gate of the transistor 44 and to the input terminal of the inverter 48. Applying a logic value 0 conceptually “opens” the switch 42. Applying a logic value 1 conceptually “closes” the switch 42. Controlling the switch 42 provides pull-down control of the I/O unit 20. The drain of the transistor 34, the source of the transistor 36, the source of the transistor 44, and the drain of the transistor 46 are coupled to the resistor 14 and to the first terminal of the transistor pair 82.

The pull-down device 60 in FIG. 2 is implemented as a PMOS transistor 64, an NMOS transistor 66, and an inverter 68. The transistor 64 and the transistor 66 are configured in parallel. The source of the transistor 64 and the drain of the transistor 66 are coupled to the power source. An input terminal of the inverter 68 is coupled to the gate of the transistor 64. An output terminal of the inverter 68 is coupled to the gate of the transistor 66. The switch 62 in FIG. 2 is implemented by applying a logic signal to the gate of the transistor 64 and to the input terminal of the inverter 68. Applying a logic value 0 conceptually “opens” the switch 62. Applying a logic value 1 conceptually “closes” the switch 62. Controlling the switch 62 provides pull-up control of the I/O unit 50.

The pull-down device 70 in FIG. 2 is implemented as a PMOS transistor 74, an NMOS transistor 76, and an inverter 78. The transistor 74 and the transistor 76 are configured in parallel. The drain of the transistor 74 and the source of the transistor 76 are coupled to ground. An input terminal of the inverter 78 is coupled to the gate of the transistor 74. An output terminal of the inverter 78 is coupled to the gate of the transistor 76. The switch 72 in FIG. 2 is implemented by applying a logic signal to the gate of the transistor 74 and to the input terminal of the inverter 78. Applying a logic value 0 conceptually “opens” the switch 72. Applying a logic value 1 conceptually “closes” the switch 72. Controlling the switch 72 provides pull-down control of the I/O unit 50. The drain of the transistor 64, the source of the transistor 66, the source of the transistor 74, and the drain of the transistor 76 are coupled to the resistor 16 and to the second terminal of the transistor pair 82.

The switch 80 in FIG. 2 is implemented by applying a logic signal to a first gate of the transistor pair 82 and to an input terminal of the inverter 84. Applying a logic value 0 conceptually “opens” the switch 80. Applying a logic value 1 conceptually “closes” the switch 80.

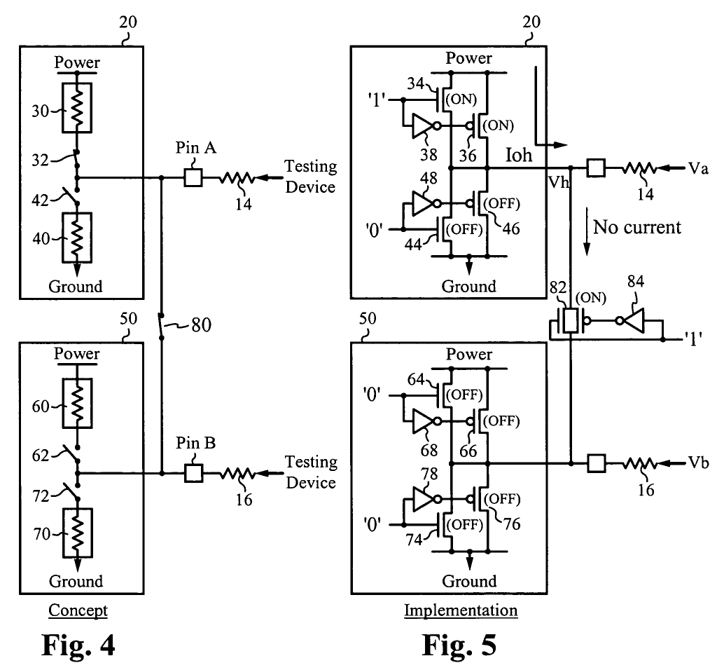

To perform a contact resistance measurement, one of the I/O units is configured at a high impedance and the other I/O unit is configured in either a pull-up mode or a pull-down mode with the switch coupling the two I/O units closed. FIG. 4 illustrates a conceptual diagram of the measuring circuit 18 configured to measure the contact resistance of the pin A using the pull-up mode. FIG. 5 illustrates an implementation of the conceptual measuring circuit 18 in FIG. 4. To measure the value of the resistor 14, which is the contact resistance of the pin A, the switch 32 and the switch 80 are closed, and the switch 42, the switch 62, and the switch 72 are open. With the switch 62 and the switch 72 open, the I/O unit 50 forms a high impedance. As implemented in FIG. 5, the switch 32 (FIG. 4) is closed by applying a logical 1 to the gate of the transistor 34 and the input terminal of the inverter 38, thereby turning on the transistor 34 and the transistor 36. The switch 42 (FIG. 4) is opened by applying a logical 0 to the gate of the transistor 44 and to the input terminal of the inverter 48, thereby turning off the transistor 44 and the transistor 46.

The switch 62 (FIG. 4) is opened by applying a logical 0 to the gate of the transistor 64 and to the input terminal of the inverter 68, thereby turning off the transistor 64 and the transistor 66. The switch 72 (FIG. 4) is opened by applying a logical 0 to the gate of the transistor 74 and to the input terminal of the inverter 78, thereby turning off the transistor 74 and the transistor 76. The switch 80 (FIG. 4) is closed by applying a logical 1 to the input terminal of the inverter 84 and to the gate of the first transistor in the transistor pair 82.

When the measuring circuit 18 is configured according to the pull-up mode for measuring the value of the resistor 14, as shown in FIGS. 4 and 5, and a voltage Va is applied to a second terminal of the resistor 14, a current Ioh flows from the power source, through the transistor 34 and the transistor 36, and through the resistor 14. As such, there is a voltage drop across the resistor 14. In this configuration, no current flows through the transistor pair 82 and no current flows through the resistor 16. As such, a voltage Vb at a second terminal of the resistor 16 is the same as a voltage Vh at the first terminal of the resistor 14. To determine the value of the resistor 14, the current Ioh is measured. and the voltage Vb is measured. The value of resistor 14 is calculated by subtracting Va from Vb and dividing the result by the current Ioh.

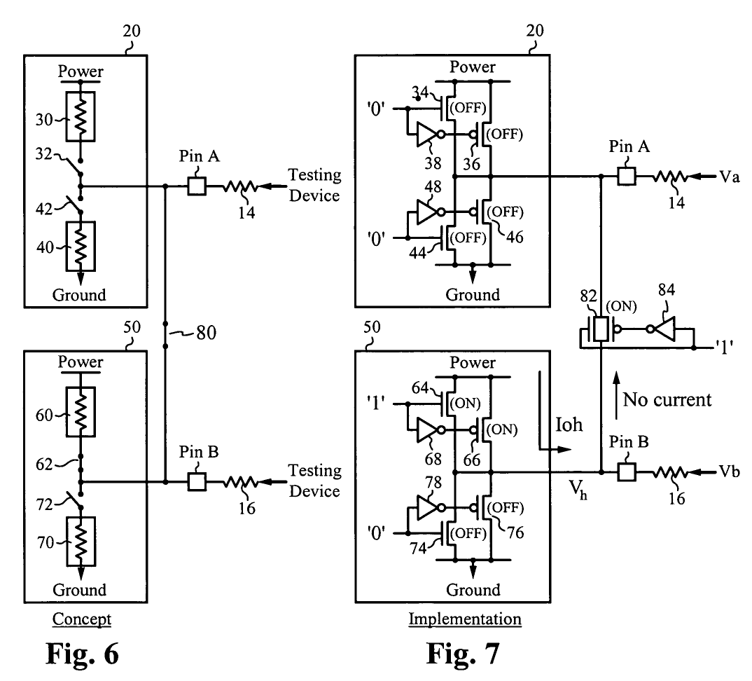

FIG. 6 illustrates a conceptual diagram of the measuring circuit 18 configured to measure the contact resistance of the pin B using the pull-up mode. FIG. 7 illustrates an implementation of the conceptual measuring circuit 18 in FIG. 6. To measure the value of the resistor 16, which is the contact resistance of the pin B, the switch 62 and the switch 80 are closed, and the switch 32, the switch 42, and the switch 72 are open. With the switch 32 and the switch 42 open, the I/O unit 20 forms a high impedance. As implemented in FIG. 7, the switch 62 (FIG. 6) is closed by applying a logical 1 to the gate of the transistor 64 and the input terminal of the inverter 68, thereby turning on the transistor 64 and the transistor 66. The switch 72 (FIG. 6) is opened by applying a logical 0 to the gate of the transistor 74 and to the input terminal of the inverter 78, thereby turning off the transistor 74 and the transistor 76.

The switch 32 (FIG. 6) is opened by applying a logical 0 to the gate of the transistor 34 and to the input terminal of the inverter 38, thereby turning off the transistor 34 and the transistor 36. The switch 42 (FIG. 6) is opened by applying a logical 0 to the gate of the transistor 44 and to the input terminal of the inverter 48, thereby turning off the transistor 44 and the transistor 46. The switch 80 (FIG. 6) is closed by applying a logical 1 to the first terminal of the inverter 84 and to the gate of the first transistor in the transistor pair 82.

When the measuring circuit 18 is configured according to the pull-up mode for measuring the value of the resistor 16, as shown in FIGS. 6 and 7, and a voltage Vb is applied to a second terminal of the resistor 16, a current Ioh flows from the power source, through the transistor 64 and the transistor 66, and through the resistor 16. As such, there is a voltage drop across the resistor 16. In this configuration, no current flows through the transistor pair 82 and no current flows through the resistor 14. As such, a voltage Va at a second terminal of the resistor 14 is the same as a voltage Vh at the first terminal of the resistor 16. To determine the value of the resistor 16, the current Ioh is measured. and the voltage Va is measured. The value of resistor 16 is calculated by subtracting Vb from Va and dividing the result by the current Ioh.

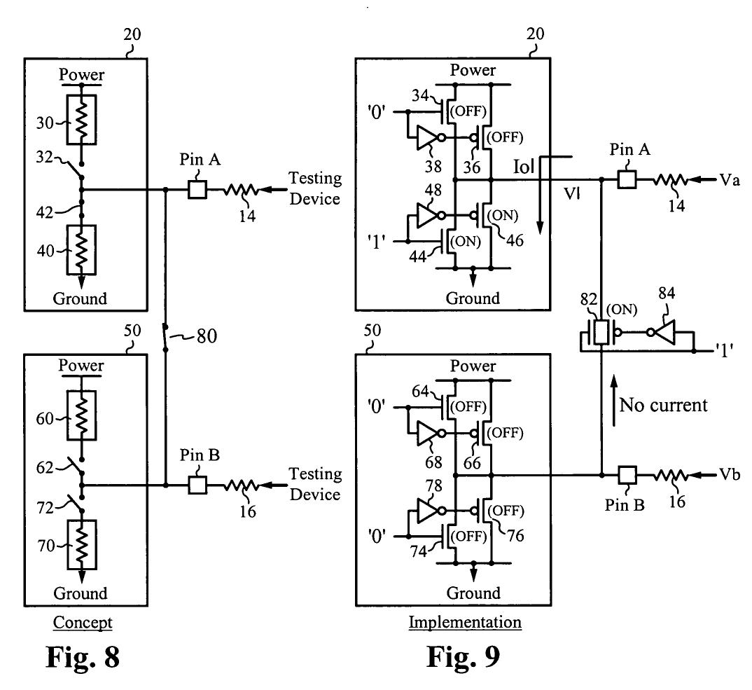

FIG. 8 illustrates a conceptual diagram of the measuring circuit 18 configured to measure the contact resistance of the pin A using the pull-down mode. FIG. 9 illustrates an implementation of the conceptual measuring circuit 18 in FIG. 8. To measure the value of the resistor 14, which is the contact resistance of the pin A, the switch 42 and the switch 80 are closed, and the switch 32, the switch 62, and the switch 72 are open. With the switch 62 and the switch 72 open, the I/O unit 50 forms a high impedance. As implemented in FIG. 9, the switch 42 (FIG. 8) is closed by applying a logical 1 to the gate of the transistor 44 and the input terminal of the inverter 48, thereby turning on the transistor 44 and the transistor 46. The switch 32 (FIG. 8) is opened by applying a logical 0 to the gate of the transistor 34 and to the input terminal of the inverter 38, thereby turning off the transistor 34 and the transistor 36.

The switch 62 (FIG. 8) is opened by applying a logical 0 to the gate of the transistor 64 and to the input terminal of the inverter 68, thereby turning off the transistor 64 and the transistor 66. The switch 72 (FIG. 8) is opened by applying a logical 0 to the gate of the transistor 74 and to the input terminal of the inverter 78, thereby turning off the transistor 74 and the transistor 76. The switch 80 (FIG. 8) is closed by applying a logical 1 to the input terminal of the inverter 84 and to the gate of the first transistor in the transistor pair 82.

When the measuring circuit 18 is configured according to the pull-down mode for measuring the value of the resistor 14, as shown in FIGS. 8 and 9, and a voltage Va is applied to a second terminal of the resistor 14, a current Iol flows from the testing device, through the resistor 14, and through the transistor 44 and the transistor 46 to ground. As such, there is a voltage drop across the resistor 14. In this configuration, no current flows through the transistor pair 82 and no current flows through the resistor 16. As such, a voltage Vb at a second terminal of the resistor 16 is the same as a voltage Vl at the first terminal of the resistor 14. To determine the value of the resistor 14, the current Ioh is measured. and the voltage Vb is measured. The value of resistor 14 is calculated by subtracting Va from Vb and dividing the result by the current Iol.

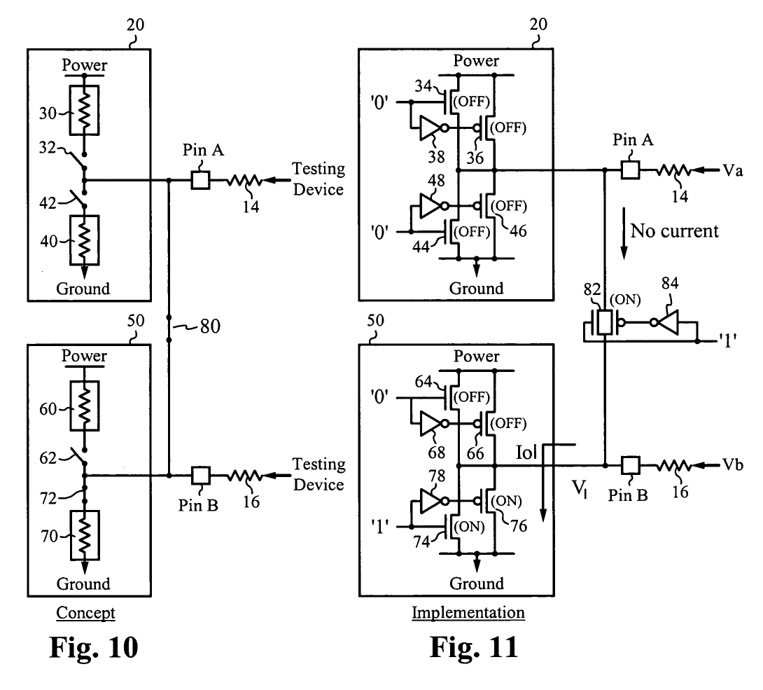

FIG. 10 illustrates a conceptual diagram of the measuring circuit 18 configured to measure the contact resistance of the pin B using the pull-down mode. FIG. 11 illustrates an implementation of the conceptual measuring circuit 18 in FIG. 10. To measure the value of the resistor 16, which is the contact resistance of the pin B, the switch 72 and the switch 80 are closed, and the switch 32, the switch 42, and the switch 62 are open. With the switch 32 and the switch 42 open, the I/O unit 20 forms a high impedance. As implemented in FIG. 11, the switch 72 (FIG. 10) is closed by applying a logical 1 to the gate of the transistor 74 and the input terminal of the inverter 78, thereby turning on the transistor 74 and the transistor 76. The switch 62 (FIG. 10) is opened by applying a logical 0 to the gate of the transistor 64 and to the input terminal of the inverter 68, thereby turning off the transistor 64 and the transistor 66.

The switch 32 (FIG. 10) is opened by applying a logical 0 to the gate of the transistor 34 and to the input terminal of the inverter 38, thereby turning off the transistor 34 and the transistor 36. The switch 42 (FIG. 10) is opened by applying a logical 0 to the gate of the transistor 44 and to the input terminal of the inverter 48, thereby turning off the transistor 44 and the transistor 46. The switch 80 (FIG. 10) is closed by applying a logical 1 to the first terminal of the inverter 84 and to the gate of the first transistor in the transistor pair 82.

When the measuring circuit 18 is configured according to the pull-down mode for measuring the value of the resistor 16, as shown in FIGS. 10 and 11, and a voltage Vb is applied to a second terminal of the resistor 16, a current Iol flows from the testing device, through the resistor 16, and through the transistor 74 and the transistor 76 to ground. As such, there is a voltage drop across the resistor 16. In this configuration, no current flows through the transistor pair 82 and no current flows through the resistor 14. As such, a voltage Va at a second terminal of the resistor 14 is the same as a voltage Vl at the first terminal of the resistor 16. To determine the value of the resistor 16, the current Iol is measured. and the voltage Va is measured. The value of resistor 16 is calculated by subtracting Vb from Va and dividing the result by the current Iol.

In operation, the measuring circuit 18 determines the contact resistance of the testing device 12 using either a pull-up mode or a pull-down mode. In the pull-up mode, the contact resistance of the pin A of the testing device 12 is determined by closing the switch 32 and the switch 80, and opening the switch 42, the switch 62, and the switch 72. The voltage Va is applied to the second terminal of the resistor 14, which represents the contact resistance of the pin A. While the voltage Va is applied, the current Ioh flowing through the resistor 14 is measured, and the voltage Vb at the second terminal of the resistor 16, which represents the contact resistance of the pin B, is also measured. The value of the resistor 14 is then calculated by dividing the voltage drop across the resistor 14, which is the voltage Vb minus the voltage Va, by the current Ioh. The contact resistance of the pin B, represented by the resistor 16, is similarly determined by closing the switch 62 and the switch 80, and opening the switch 32, the switch 42, and the switch 72. The voltage Vb is applied to the second terminal of the resistor 16. While the voltage Vb is applied, the current Ioh flowing through the resistor 16 is measured, and the voltage Va at the second terminal of the resistor 14 is measured. The value of the resistor 16 is then calculated by dividing the voltage drop across the resistor 16, which is the voltage Va minus the voltage Vb, by the current Ioh.

In the pull-down mode, the contact resistance of pin A is determined by closing the switch 42 and the switch 80, and opening the switch 32, the switch 62, and the switch 72. The voltage Va is applied to the second terminal of the resistor 14. While the voltage Va is applied, the current Iol flowing through the resistor 14 is measured, and the voltage Vb at the second terminal of the resistor 16 is also measured. The value of the resistor 14 is then calculated by dividing the voltage drop across the resistor 14, which is the voltage Va minus the voltage Vb, by the current Iol. The contact resistance of the pin B, represented by the resistor 16, is similarly determined by closing the switch 72 and the switch 80, and opening the switch 32, the switch 42, and the switch 62. The voltage Vb is applied to the second terminal of the resistor 16. While the voltage Vb is applied, the current Iol flowing through the resistor 16 is measured, and the voltage Va at the second terminal of the resistor 14 is measured. The value of the resistor 16 is then calculated by dividing the voltage drop across the resistor 16, which is the voltage Vb minus the voltage Va, by the current Iol. The contact resistances of the pin A and the pin B are used to calibrate the testing device 12.

Although the measuring circuit is described above as being configured to measure the contact resistance of two contact points, pin A and pin B, of the testing device, the measuring circuit can be configured to measure the contact resistance of any number of contact points, depending on the configuration of the testing device.

The measuring circuit provides a quick and simple means to calibrate a testing device contact resistance prior to wafer or device testing. The measuring circuit also provides a debug test setup for poor pin contact.

The present invention has been described in terms of specific embodiments incorporating details to facilitate the understanding of the principles of construction and operation of the invention. Such references, herein, to specific embodiments and details thereof are not intended to limit the scope of the claims appended hereto. It will be apparent to those skilled in the art that modifications can be made in the embodiments chosen for illustration without departing from the spirit and scope of the invention.

What is claimed is:

1. A method of determining a contact resistance of a testing device, the method comprising:
coupling a first pin of the testing device to a first pull-up device and coupling a second pin of the testing device to a second pull-up device;
coupling the first pull-up device to the second pull-up device via a pass device;
configuring the first pull-up device and the pass device to an on-state;
configuring the second pull-up device to an off-state, thereby configuring the second pull-up device as a high impedance circuit path;
applying a first voltage to the first pin;
measuring a first current entering the first pin;
measuring a second voltage at the second pin; and
calculating a contact resistance of the first pin according to the applied first voltage, the measured second voltage, and the measured first current.

2. The method of claim 1 further comprising coupling a first pull-down device in series with the first pull-up device such that the first pin is coupled to a first terminal of the first pull-up device and to a first terminal of the first pull-down device.

3. The method of claim 2 further comprising configuring the first pull-down device to an off-state.

4. The method of claim 3 further comprising coupling a second pull-down device in series with the second pull-up device such that the second pin is coupled to a first terminal of the second pull-up device and to a first terminal of the second pull-down device.

5. The method of claim 4 further comprising configuring the second pull-down device to an off-state.

6. The method of claim 5 further comprising coupling a second terminal of the first pull-up device and a second terminal of the second pull-up device to a power source and coupling a second terminal of the first pull-down device and a second terminal of the second pull-down device to ground.

7. The method of claim 1 wherein the contact resistance of the first pin is represented as a first resistor and the contact resistance of the second pin is represented as a second resistor.

8. The method of claim 7 wherein coupling the first pin to the first pull-up device comprises coupling a first terminal of the first resistor to the first pull-up device, applying the first voltage to the first pin comprises applying the first voltage to a second terminal of the first resistor, and measuring the first current entering the first pin comprises measuring the first current at the first terminal of the first resistor.

9. The method of claim 7 wherein coupling the second pin to the second pull-up device comprises coupling a first terminal of the second resistor to the second pull-up device, and measuring the second voltage at the second pin comprises measuring the second voltage at a second terminal of the second resistor.

10. The method of claim 1 further comprising:
configuring the second pull-up device and the pass device to an on-state;
configuring the first pull-up device to an off-state, thereby configuring the first pull-up device as a high impedance circuit path;
removing the applied first voltage from the first pin;
applying a third voltage to the second pin;
measuring a second current entering the second pin;
measuring a fourth voltage at the second pin; and
calculating a contact resistance of the second pin according to the applied third voltage, the measured fourth voltage, and the measured second current.

11. The method of claim 10 wherein configuring a device to the on-state comprises applying a logical high signal to the device, and configuring the device to the off-state comprises applying a logical low signal to the device.

12. A method of determining a contact resistance of a testing device, the method comprising:
coupling a first pin of the testing device to a first pull-down device and coupling a second pin of the testing device to a second pull-down device;
coupling the first pull-down device to the second pull-down device via a pass device;
configuring the first pull-down device and the pass device to an on-state;
configuring the second pull-down device to an off-state, thereby configuring the second pull-down device as a high impedance circuit path;
applying a first voltage to the first pin;
measuring a first current being output from the first pin;
measuring a second voltage at the second pin; and
calculating a contact resistance of the first pin according to the applied first voltage, the measured second voltage, and the measured first current.

13. The method of claim 12 further comprising coupling a first pull-up device in series with the first pull-down device such that the first pin is coupled to a first terminal of the first pull-up device and to a first terminal of the first pull-down device.

14. The method of claim 13 further comprising configuring the first pull-up device to an off-state.

15. The method of claim 14 further comprising coupling a second pull-up device in series with the second pull-down device such that the second pin is coupled to a first terminal of the second pull-up device and to a first terminal of the second pull-down device.

16. The method of claim 15 further comprising configuring the second pull-up device to an off-state.

17. The method of claim 16 further comprising coupling a second terminal of the first pull-up device and a second terminal of the second pull-up device to a power source and coupling a second terminal of the first pull-down device and a second terminal of the second pull-down device to ground.

18. The method of claim 12 wherein the contact resistance of the first pin is represented as a first resistor and the contact resistance of the second pin is represented as a second resistor.

19. The method of claim 18 wherein coupling the first pin to the first pull-down device comprises coupling a first terminal of the first resistor to the first pull-down device, applying the first voltage to the first pin comprises applying the first voltage to a second terminal of the first resistor, and measuring the first current being output from the first pin comprises measuring the first current at the first terminal of the first resistor.

20. The method of claim 19 wherein coupling the second pin to the second pull-down device comprises coupling a first terminal of the second resistor to the second pull-down device, and measuring the second voltage at the second pin comprises measuring the second voltage at a second terminal of the second resistor.

21. The method of claim 12 further comprising:
configuring the second pull-down device and the pass device to an on-state;
configuring the first pull-down device to an off-state, thereby configuring the first pull-down device as a high impedance circuit path;
removing the applied first voltage from the first pin;
applying a third voltage to the second pin;
measuring a second current being output from the second pin;
measuring a fourth voltage at the second pin; and
calculating a contact resistance of the second pin according to the applied third voltage, the measured fourth voltage, and the measured second current.

22. The method of claim 21 wherein configuring a device to the on-state comprises applying a logical high signal to the device, and configuring the device to the off-state comprises applying a logical low signal to the device.

23. A circuit to determine a contact resistance of a testing device, the circuit comprising:
a first pull-up device coupled to a first pin of the testing device, wherein the first pull-up device is configured to be dynamically set to either an on-state or an off-state;
a second pull-up device coupled to a second pin of the testing device, wherein the second pull-up device is configured to be dynamically set to either an on-state or an off-state; and
a pass device including a first terminal and a second terminal, wherein the first terminal is coupled to the first pin and to the first pull-up device, and the second terminal is coupled to the second pin and to the second pull-up device, further wherein the pass device is configured to be dynamically set to either an on-state or an off-state;
wherein the circuit is configured such that when the first pull-up device is set to the on-state, the pass device is set to the on-state, the second pull-up device is set to the off-state and a first voltage is applied to the first pin, a first current entering the first pin is measured and a second voltage at the second pin is measured to calculate a contact resistance of the first pin.

24. The circuit of claim 23 further comprises a processing circuit configured to calculate the contact resistance of the first pin according to the applied first voltage, the measured second voltage, and the measured first current.

25. The circuit of claim 23 further comprising a first pull-down device coupled in series with the first pull-up device such that the first pin is coupled to a first terminal of the first pull-up device and to a first terminal of the first pull-down device.

26. The circuit of claim 25 wherein the first pull-down device is set to an off-state.

27. The circuit of claim 26 further comprising a second pull-down device coupled in series with the second pull-up device such that the second pin is coupled to a first terminal of the second pull-up device and to a first terminal of the second pull-down device.

28. The circuit of claim 27 wherein the second pull-down device is set to an off-state.

29. The circuit of claim 28 wherein a second terminal of the first pull-up device and a second terminal of the second pull-up device are coupled to a power source and a second terminal of the first pull-down device and a second terminal of the second pull-down device are coupled to ground.

30. The circuit of claim 23 wherein the contact resistance of the first pin is represented as a first resistor and the contact resistance of the second pin is represented as a second resistor.

31. The circuit of claim 30 wherein a first terminal of the first resistor is coupled to the first pull-up device, the first voltage is applied to a second terminal of the first resistor, and the first current is measured at the first terminal of the first resistor.

32. The circuit of claim 30 wherein a first terminal of the second resistor is coupled to the second pull-up device, and the second voltage is measured at a second terminal of the second resistor.

33. The circuit of claim 23 wherein the circuit is configured such that when the second pull-up device and the pass device are set to the on-state, the first pull-up device is set to the off-state, the applied first voltage is removed from the first pin, and a third voltage is applied to the second pin, a second current entering the second pin is measured and a fourth voltage is measured at the second pin to calculate a contact resistance of the second pin.

34. The circuit of claim 33 further comprising a processing circuit configured to calculate the contact resistance of the second pin according to the applied third voltage, the measured fourth voltage, and the measured second current.

35. The circuit of claim 23 wherein a device is configured to the on-state by applying a logical high signal to the device, and the device is configured to the off-state by applying a logical low signal to the device.

36. The circuit of claim 23 wherein the testing device comprises a semiconductor testing device.

37. A circuit to determine a contact resistance of a testing device, the circuit comprising:
a first pull-down device coupled to a first pin of the testing device, wherein the first pull-down device is configured to be dynamically set to either an on-state or an off-state;
a second pull-down device coupled to a second pin of the testing device, wherein the second pull-down device is configured to be dynamically set to either an on-state or an off-state; and
a pass device including a first terminal and a second terminal, wherein the first terminal is coupled to the first pin and to the first pull-down device, and the second terminal is coupled to the second pin and to the second pull-down device, further wherein the pass device is configured to be dynamically set to either an on-state or an off-state;
wherein the circuit is configured such that when the first pull-down device is set to the on-state, the pass device is set to the on-state, the second pull-down device is set to the off-state and a first voltage is applied to the first pin, a first current being output by the first pin is measured and a second voltage at the second pin is measured to calculate a contact resistance of the first pin.

38. The circuit of claim 37 further comprises a processing circuit configured to calculate the contact resistance of the first pin according to the applied first voltage, the measured second voltage, and the measured first current.

39. The circuit of claim 37 further comprising a first pull-up device coupled in series with the first pull-down device such that the first pin is coupled to a first terminal of the first pull-up device and to a first terminal of the first pull-down device.

40. The circuit of claim 39 wherein the first pull-up device is set to an off-state.

41. The circuit of claim 40 further comprising a second pull-up device coupled in series with the second pull-down device such that the second pin is coupled to a first terminal of the second pull-up device and to a first terminal of the second pull-down device.

42. The circuit of claim 41 wherein the second pull-up device is set to an off-state.

43. The circuit of claim 42 wherein a second terminal of the first pull-up device and a second terminal of the second pull-up device are coupled to a power source and a second terminal of the first pull-down device and a second terminal of the second pull-down device are coupled to ground.

44. The circuit of claim 37 wherein the contact resistance of the first pin is represented as a first resistor and the contact resistance of the second pin is represented as a second resistor.

45. The circuit of claim 44 wherein a first terminal of the first resistor is coupled to the first pull-down device, the first voltage is applied to a second terminal of the first resistor, and the first current is measured at the first terminal of the first resistor.

46. The circuit of claim 44 wherein a first terminal of the second resistor is coupled to the second pull-down device, and the second voltage is measured at a second terminal of the second resistor.

47. The circuit of claim 37 wherein the circuit is configured such that when the second pull-down device and the pass device are set to the on-state, the first pull-down device is set to the off-state, the applied first voltage is removed from the first pin, and a third voltage is applied to the second pin, a second current entering the second pin is measured and a fourth voltage is measured at the second pin to calculate a contact resistance of the second pin.

48. The circuit of claim 47 further comprising a processing circuit configured to calculate the contact resistance of the second pin according to the applied third voltage, the measured fourth voltage, and the measured second current.

49. The circuit of claim 37 wherein a device is configured to the on-state by applying a logical high signal to the device, and the device is configured to the off-state by applying a logical low signal to the device.

50. The circuit of claim 37 wherein the testing device comprises a semiconductor testing device.

51. A system to determine a contact resistance of a testing device, the system comprising:
the testing device including a first pin and a second pin;
a measuring circuit coupled to the measuring device and configured to measure a voltage drop across the first pin of the testing device when a first voltage is applied to the first pin, to measure a first current flowing through the first pin when the first voltage is applied to the first pin, and to measure a second voltage at the second pin of the testing device when the first voltage is applied to the first pin; and
a processing circuit coupled to the measuring circuit and configured to calculate a contact resistance of the first pin according to the applied first voltage, the measured second voltage, and the measured first current.

52. The system of claim 51 wherein the measuring circuit comprises one or more pull-up devices and a pass device dynamically configurable to enable the first current to flow through the first pin and to prevent a second current from flowing through the second pin.

53. The system of claim 51 wherein the measuring circuit comprises one or more pull-down devices and a pass device dynamically configurable to enable the first current to flow through the first pin and to prevent a second current from flowing through the second pin.

54. The system of claim 51 wherein the measuring circuit is configured such that when the first voltage is removed from the first pin and a third voltage is applied to the second pin, the circuit measures a voltage drop across the second pin of the testing device, the circuit measures a second current flowing through the second pin, and the circuit measures a fourth voltage at the first pin of the testing device.

55. The system of claim 54 wherein the processing circuit is configured to calculate a contact resistance of the second pin according to the applied third voltage, the measured fourth voltage, and the measured second current.
